(19) United States
(12) Patent Application Publication
(10) Pub. No.: US 2016/0097682 A1
(43) Pub. Date: Apr. 7, 2016

(54) PYROELECTRIC MATERIAL, MANUFACTURING METHOD OF PYROELECTRIC MATERIAL, PYROELECTRIC ELEMENT, MANUFACTURING METHOD OF PYROELECTRIC ELEMENT, THERMOELECTRIC CONVERSION ELEMENT, MANUFACTURING METHOD OF THERMOELECTRIC CONVERSION ELEMENT, THERMAL PHOTODETECTOR, MANUFACTURING METHOD OF THERMAL PHOTODETECTOR, AND ELECTRONIC INSTRUMENT

(71) Applicant: Seiko Epson Corporation, Tokyo (JP)

(72) Inventors: Yasushi TSUCHIYA, Fujimi (JP); Takayuki YONEMURA, Suwa (JP)

(21) Appl. No.: 14/874,908

(22) Filed: Oct. 5, 2015

(30) Foreign Application Priority Data
Oct. 6, 2014 (JP) 2014-205778

(51) Int. Cl. G01J 5/34; H01L 37/02; C04B 35/26; G01J 5/02

(52) U.S. Cl. CPC G01J 5/34; G01J 5/024; H01L 37/02; C04B 35/2608; G01J 2005/345; C04B 2235/3298; C04B 2235/3227; C04B 2235/3232; C04B 2235/3262

(57) ABSTRACT

A pyroelectric material is constituted with an oxide containing iron, manganese, bismuth, and lanthanum, in which a ratio of the number of the manganese atoms to the sum of the number of the iron atoms, the number of the manganese atoms, and the number of titanium atoms is equal to or greater than 1.0 at % and equal to or less than 2.0 at %, and a ratio of the number of the titanium atoms to the sum of the number of the iron atoms, the number of the manganese atoms, and the number of the titanium atoms is equal to or greater than 0 at % and equal to or less than 4.0 at %.

### BACKGROUND

1. Technical Field

The present invention relates to a pyroelectric material, a manufacturing method of a pyroelectric material, a pyroelectric element, a manufacturing method of a pyroelectric element, a thermoelectric conversion element, a manufacturing method of a thermoelectric conversion element, a thermal photodetector, a manufacturing method of a thermal photodetector, and an electronic instrument.

2. Related Art

A pyroelectric material that is a material showing a phenomenon (pyroelectric effect) in which the polarization value (surface charge) thereof varies with temperature is known.

Furthermore, as a photosensor, a thermal photodetector is known which absorbs light radiated from an object by using a light absorbing layer, converts the light into heat, and measures a change in temperature by using a thermal detection element.

There are various thermal photodetectors, and in view of excellent sensitivity, thermal photodetectors, which include a pyroelectric element constituted with a material containing a pyroelectric material, are widely used (for example, see JP-A-2013-134081).

As the material constituting the pyroelectric element, lead zirconate titanate has been used. However, from the viewpoint of environmental issues or the like, this material is not preferable because it contains lead (Pb) as a constituent element.

Although attempts have been made to use a pyroelectric material other than lead zirconate titanate, in the related art, it is difficult to accomplish both a high degree of insulating properties and a high remnant polarization value at the same time.

### SUMMARY

An advantage of some aspects of the invention is to provides a pyroelectric material that has both a high degree of insulating properties and a high remnant polarization value, a manufacturing method of a pyroelectric material that makes it possible to manufacture the pyroelectric material with excellent efficiency, a pyroelectric element that is constituted with a material containing the pyroelectric material, a manufacturing method of a pyroelectric element that makes it possible to manufacture the pyroelectric element with excellent efficiency, a thermoelectric conversion element that includes the pyroelectric element, a manufacturing method of a thermoelectric conversion element that makes it possible to manufacture the thermoelectric conversion element with excellent efficiency, a thermal photodetector that includes the pyroelectric element, a manufacturing method of a thermal photodetector that makes it possible to manufacture the thermal photodetector with excellent efficiency, and an electronic instrument that includes the thermal photodetector.

A pyroelectric material according to an aspect of the invention includes an oxide containing iron, manganese, bismuth, and lanthanum, in which a ratio of the number of the manganese atoms to the sum of the number of the iron atoms, the number of the manganese atoms, and the number of titanium atoms is equal to or greater than 1.0 at % and equal to or less than 2.0 at %, and a ratio of the number of the titanium atoms to the sum of the number of the iron atoms, the number of the manganese atoms, and the number of the titanium atoms is equal to or greater than 0 at % and equal to or less than 4.0 at %.

With this configuration, it is possible to provide a pyroelectric material that has both a high degree of insulating properties and a high remnant polarization value.

In the pyroelectric material according to the aspect of the invention, it is preferable that a ratio of the number of lanthanum atoms to the sum of the number of bismuth atoms and the number of lanthanum atoms is equal to or greater than 10 at % and equal to or less than 20 at %.

With this configuration, a remnant polarization value and a pyroelectric coefficient can be further increased.

A manufacturing method of a pyroelectric material according to another aspect of the invention includes heating a solution obtained by dissolving fatty acid metal salts in an organic solvent so as to manufacture a pyroelectric material constituted with an oxide containing iron, manganese, bismuth, and lanthanum, in which in the pyroelectric material, a ratio of the number of the manganese atoms to the sum of the number of the iron atoms, the number of the manganese atoms, and the number of titanium atoms is equal to or greater than 1.0 at % and equal to or less than 2.0 at %, and a ratio of the number of the titanium atoms to the sum of the number of the iron atoms, the number of the manganese atoms, and the number of the titanium atoms is equal to or greater than 0 at % and equal to or less than 4.0 at %.

With this configuration, it is possible to provide a manufacturing method of a pyroelectric material that makes it possible to manufacture a pyroelectric material, which has both a high degree of insulating properties and a high remnant polarization value, with excellent efficiency.

A pyroelectric element according to still another aspect of the invention includes a first electrode, the pyroelectric material according to the aspect of the invention, and a second electrode.

With this configuration, it is possible to provide a highly reliable pyroelectric element including a pyroelectric material which has both a high degree of insulating properties and a high remnant polarization value.

A pyroelectric element according to yet another aspect of the invention includes a pyroelectric material manufactured by a manufacturing method of a pyroelectric material according to the aspect of the invention.

With this configuration, it is possible to provide a highly reliable pyroelectric element including a pyroelectric material which has both a high degree of insulating properties and a high remnant polarization value.

A manufacturing method of a pyroelectric element according to still yet another aspect of the invention includes laminating a first electrode, the pyroelectric material according to the aspect of the invention, and a second electrode on each other.

With this configuration, it is possible to provide a manufacturing method of a pyroelectric element that makes it possible to manufacture a highly reliable pyroelectric element including a pyroelectric material, which has both a high degree of insulating properties and a high remnant polarization value, with excellent efficiency.

A thermoelectric conversion element according to further another aspect of the invention includes the pyroelectric element according to the aspect of the invention, a light absorbing layer, and an insulating layer which is disposed between the pyroelectric element and the light absorbing layer.

With this configuration, it is possible to provide a highly reliable thermoelectric conversion element including a pyroelectric material which has both a high degree of insulating properties and a high remnant polarization value.

A manufacturing method of a thermoelectric conversion element according to still further another aspect of the invention includes forming the pyroelectric element according to the aspect of the invention, and forming a light absorbing layer via an insulating layer such that the light absorbing layer covers at least a portion of the pyroelectric element.

With this configuration, it is possible to provide a manufacturing method of a thermoelectric conversion element that makes it possible to manufacture a highly reliable thermoelectric conversion element including a pyroelectric material, which has both a high degree of insulating properties and a high remnant polarization value, with excellent efficiency.

A thermal photodetector according to yet further another aspect of the invention includes the pyroelectric element according to the aspect of the invention.

With this configuration, it is possible to provide a highly reliable thermal photodetector including a pyroelectric material which has both a high degree of insulating properties and a high remnant polarization value.

A thermal photodetector according to still yet further another aspect of the invention includes the pyroelectric element manufactured by the manufacturing method of a pyroelectric element according to the aspect of the invention.

With this configuration, it is possible to provide a highly reliable thermal photodetector including a pyroelectric material which has both a high degree of insulating properties and a high remnant polarization value.

A manufacturing method of a thermal photodetector according to a further aspect of the invention includes: preparing a base member having a substrate and a sacrificial layer; forming a support member on a surface of the base member that is a surface on which the sacrificial layer is disposed; forming the pyroelectric element according to the aspect of the invention on the support member; forming alight absorbing layer via an insulating layer such that the light absorbing layer covers the outer surface of the pyroelectric element; patterning the support member; and etching the sacrificial layer.

With this configuration, it is possible to provide a manufacturing method of a thermal photodetector that makes it possible to manufacture a highly reliable thermal photodetector including a pyroelectric material, which has both a high degree of insulating properties and a high remnant polarization value, with excellent efficiency.

An electronic instrument according to a still further aspect of the invention includes the thermal photodetector according to the aspect of the invention.

With this configuration, it is possible to provide a highly reliable electronic instrument including a pyroelectric material which has both a high degree of insulating properties and a high remnant polarization value.

An electronic instrument according to a yet further aspect of the invention includes a thermal photodetector manufactured by the manufacturing method of a thermal photodetector according to the aspect of the invention.

With this configuration, it is possible to provide a highly reliable electronic instrument including a pyroelectric material which has both a high degree of insulating properties and a high remnant polarization value.

### BRIEF DESCRIPTION OF THE DRAWINGS

The invention will be described with reference to the accompanying drawings, wherein like numbers reference like elements.

FIG. 1 is a plan view of a thermal photodetector in a first embodiment of the invention.

FIG. 2 is a sectional view taken along line A-A in FIG. 1.

FIGS. 3A and 3B are views in which main steps in a manufacturing method of a thermal photodetector in the first embodiment of the invention are illustrated in chronological order.

FIGS. 4A and 4B are views in which main steps in the manufacturing method of a thermal photodetector in the first embodiment of the invention are illustrated in chronological order.

FIGS. 5A and 5B are views in which main steps in the manufacturing method of a thermal photodetector in the first embodiment of the invention are illustrated in chronological order.

FIGS. 6A and 6B are views in which main steps in the manufacturing method of a thermal photodetector in the first embodiment of the invention are illustrated in chronological order.

FIG. 7 is a plan view of a thermal photodetector in a second embodiment of the invention.

FIG. 8 is a plan view showing a thermal photodetection apparatus in a third embodiment of the invention.

FIG. 9 is a view showing the constitution of an electronic instrument of a preferred embodiment of the invention.

FIGS. 10A and 10B are views showing the constitution of a sensor device of the electronic instrument of the preferred embodiment of the invention.

FIG. 11 is a view showing the constitution of a terahertz camera as the electronic instrument of the preferred embodiment of the invention.

### DESCRIPTION OF EXEMPLARY EMBODIMENTS

Hereinafter, preferred embodiments of the invention will be specifically described with reference to the attached drawings.

### Pyroelectric Material

First, a pyroelectric material according to the invention will be described.

The pyroelectric material according to the invention is constituted with an oxide containing iron, manganese, bismuth, and lanthanum.

A ratio of the number of the manganese (Mn) atoms to the sum of the number of the iron (Fe) atoms, the number of the manganese (Mn) atoms, and the number of titanium (Ti) atoms is equal to or greater than 1.0 at % and equal to or less than 2.0 at %. Furthermore, a ratio of the number of the titanium (Ti) atoms to the sum of the number of the iron (Fe) atoms, the number of the manganese (Mn) atoms, and the number of the titanium (Ti) atoms is equal to or greater than 0 at % and equal to or less than 4.0 at %.

If the aforementioned constitution is adopted, a pyroelectric material having both a high degree of insulating properties and a high remnant polarization value can be obtained.

In contrast, if the aforementioned conditions are not satisfied, satisfactory results are not obtained.

For example, if the ratio of the manganese atoms to the sum of the number of iron atoms, the number of manganese atoms, and the number of titanium atoms is less than the aforementioned lower limit, the insulating properties of the pyroelectric material deteriorate. Consequently, when a relatively high voltage (for example, about 12 V) is applied to the pyroelectric material, a leakage current increases. When the ratio of the number of manganese atoms to the sum of the number of iron atoms, the number of manganese atoms, and the number of titanium atoms is less than the aforementioned lower limit, if the ratio of the number of titanium atoms to the sum of the number of iron atoms, the number of manganese atoms, and the number of titanium atoms is increased, the leakage current can be reduced. However, in this case, the polarization value of the pyroelectric material is markedly reduced.

If the ratio of the number of manganese atoms to the sum of the number of iron atoms, the number of manganese atoms, and the number of titanium atoms is greater than the aforementioned upper limit, the insulating properties of the pyroelectric material deteriorate. Consequently, when a relatively low voltage (for example, about 60 μV) is applied to the pyroelectric material, the leakage current increases.

If the ratio of the number of titanium atoms to the sum of the number of iron atoms, the number of manganese atoms, and the number of titanium atoms is greater than the aforementioned upper limit, a polarization value and a pyroelectric coefficient of the pyroelectric material are reduced. Accordingly, when the pyroelectric material is applied to, for example, a pyroelectric element constituting a thermal photodetector, the sensitivity thereof to temperature is reduced.

As described above, in the invention, the ratio of the number of the manganese atoms to the sum of the number of the iron atoms, the number of the manganese atoms, and the number of the titanium atoms may be equal to or greater than 1.0 at % and equal to or less than 2.0 at %, preferably equal to or greater than 1.0 at % and equal to or less than 1.8 at %, and more preferably equal to or greater than 1.0 at % and equal to or less than 1.6 at %.

If the ratio is within the above range, the effects described above are more markedly exhibited.

A ratio of the number of titanium atoms to the sum of the number of iron atoms, the number of manganese atoms, and the number of titanium atoms may be equal to or greater than 0 at % and equal to or less than 4.0 at %, preferably equal to or greater than 0.2 at % and equal to or less than 3.7 at %, and more preferably equal to or greater than 1.5 at % and equal to or less than 3.5 at %.

If the ratio is within the above range, the effects described above are more markedly exhibited. Furthermore, it is possible to further reduce the leakage current that occurs when a relatively low voltage (for example, about 60 μV) is applied to the pyroelectric material.

A ratio of the number of the iron atoms to the sum of the number of the iron atoms, the number of the manganese atoms, and the number of the titanium atoms is preferably equal to or greater than 94.5 at % and equal to or less than 98.8 at %, and more preferably equal to or greater than 94.9 at % and equal to or less than 97.5 at %.

If the ratio is within the above range, the effects described above are more markedly exhibited.

A ratio of the number of the lanthanum atoms to the sum of the number of the bismuth atoms and the number of the lanthanum atoms is preferably equal to or greater than 10 at % and equal to or less than 20 at %, and more preferably equal to or greater than 12 at % and equal to or less than 18 at %.

If the ratio is within the above range, it is possible to further increase the remnant polarization value and the pyroelectric coefficient.

Generally, the pyroelectric material according to the invention has a perovskite-type crystal structure with high regularity.

As described above, the pyroelectric material according to the invention may be constituted with an oxide containing iron, manganese, bismuth, and lanthanum, and the oxide may contain one kind or two or more kinds of elements (other elements) other than iron, manganese, bismuth, lanthanum, and oxygen.

In this case, the amount of the other elements contained in the oxide is preferably equal to or less than 1.0 at %, and more preferably equal to or less than 0.5 at %.

If the amount of the other elements is within the above range, the aforementioned effects of the invention can be more effectively exhibited.

Examples of the other elements constituting the oxide include lanthanoid (neodymium, gadolinium, cerium, or the like), barium, calcium, cobalt, and the like.

The pyroelectric material according to the invention may contain one kind or two or more kinds of components (other components) other than the oxide (oxide containing iron, manganese, bismuth, and lanthanum).

In this case, the amount of the other components (components other than the aforementioned oxide) contained in the pyroelectric material is preferably equal to or less than 2.0% by mass, and more preferably equal to or less than 1.0% by mass.

If the amount of the other components is as above, the aforementioned effects of the invention can be more effectively exhibited.

Examples of the other components (components other than the aforementioned oxide) contained in the pyroelectric material include an oxide other than the aforementioned oxide (oxide containing iron, manganese, bismuth, and lanthanum), lanthanoid (neodymium, gadolinium, cerium, or the like), barium, calcium, cobalt, and the like.

Manufacturing method of pyroelectric material

Next, a manufacturing method of a pyroelectric material according to the invention will be described.

The aforementioned pyroelectric material according to the invention may be manufactured by any method. However, it is preferable that the pyroelectric material is manufactured by heating a solution obtained by dissolving a fatty acid metal salt in an organic solvent.

If the pyroelectric material is manufactured by the aforementioned method, it is possible to manufacture a pyroelectric material, which has both a high degree of insulating properties and a high remnant polarization value, with excellent efficiency.

As the fatty acid metal salt, a fatty acid metal salt may be used for a portion of metal elements among the metal elements constituting the aforementioned oxide. However, it is preferable that the fatty acid metal salt is used for each of the metal elements that are essential constituents of the oxide, that is, for each of iron, manganese, bismuth, and lanthanum.

Examples of the fatty acid constituting the fatty acid metal salt include formic acid, acetic acid, propionic acid, butyric acid, valeric acid, caproic acid, enantoic acid, caprylic acid, and the like. The fatty acid is particularly preferably acetic acid.

If the fatty acid metal salt is used in the manner described above, the solubility of the fatty acid metal salt in an organic solvent can become suitable, and the fatty acid metal salt can easily cause a chemical reaction with the aforementioned oxide.

In a case of using the fatty acid metal salt for a plurality of kinds of metal elements, the same kind of fatty acid or different kinds of fatty acids may be used for each of the metal elements.

Furthermore, a single fatty acid or a combination of a plurality of kinds of fatty acids may be used for the fatty acid metal salt of any metal element.

Examples of the organic solvent dissolving the fatty acid metal salt include a fatty acid such as formic acid, acetic acid, propionic acid, butyric acid, valeric acid, caproic acid, enantoic acid, or caprylic acid; (poly)alkylene glycol monoalkyl ethers such as ethylene glycol monomethyl ether, ethylene glycol monoethyl ether, propylene glycol monomethyl ether, and propylene glycol monoethyl ether; fatty acid esters such as ethyl acetate, n-propyl acetate, iso-propyl acetate, n-butyl acetate, and iso-butyl acetate; aromatic hydrocarbons such as benzene, toluene, and xylene; ketones such as methyl ethyl ketone, acetone, methyl isobutyl ketone, ethyl-n-butyl ketone, diisopropyl ketone, and acetyl acetone; alcohols such as ethanol, propanol, butanol, ethylene glycol, and glycerin; and the like. One kind of organic solvent selected from these may be used alone, or two or more kinds of solvents selected from these may be used in combination. However, it is preferable to use a fatty acid.

Generally, the fatty acid makes the fatty acid metal salt exhibit particularly excellent solubility and has appropriate viscosity. Accordingly, the fatty acid makes it easy to handle a solvent or a solution, and can more effectively prevent the composition of the pyroelectric material to be manufactured from being unintentionally varied from site to site. Moreover, the fatty acid generally has an appropriately high boiling point. Consequently, the chemical reaction between the fatty acid metal salt and the aforementioned oxide caused by heating can suitably proceed.

As the fatty acid used as the organic solvent dissolving the fatty acid metal salt, propionic acid is particularly preferable.

If the fatty acid is used in the manner described above, the solubility of the fatty acid metal salt in an organic solvent can become suitable, and the fatty acid metal salt can easily cause a chemical reaction with the aforementioned oxide. Moreover, it is possible to perform the chemical reaction at a relatively high temperature by using a simple device or apparatus, and to easily remove the solvent after the chemical reaction. As a result, the productivity of the pyroelectric material can become particularly excellent, and it is possible to more reliably prevent the solvent from unintentionally remaining in the obtained pyroelectric material.

The heating temperature (reaction temperature) of the solution obtained by dissolving the fatty acid metal salt in an organic solvent is not particularly limited. However, the heating temperature is preferably equal to or higher than 90° C. and equal to or less than 250° C., and more preferably equal to or higher than 100° C. and equal to or less than 200° C.

If the heating temperature is within the above range, it is possible to prevent the composition of the obtained pyroelectric material from being unintentionally varied, and to manufacture the pyroelectric material having an intended composition with higher productivity.

### Pyroelectric Element, Thermoelectric Conversion Element, and Thermal Photodetector (Thermal Photodetection Apparatus)

Next, a photoelectric element, a thermoelectric conversion element, and a thermal photodetector according to the invention will be described.

### First Embodiment

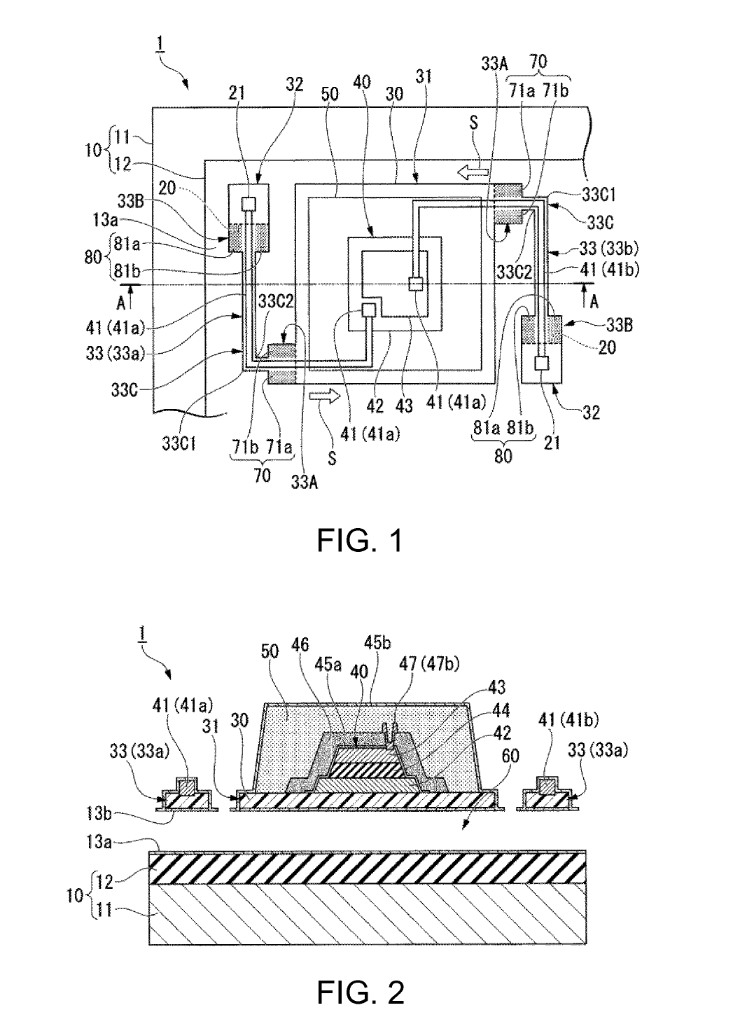

FIG. 1 is a plan view showing a thermal photodetector according to a first embodiment of the invention, and FIG. 2 is a sectional view taken along line A-A in FIG. 1.

A thermal photodetector 1 shown in FIGS. 1 and 2 is a pyroelectric infrared detector (a type of photosensor). The thermal photodetector 1 converts the heat, which is generated as a result of absorption of light into a light absorbing layer 50, into electric signals in a thermal detection element (pyroelectric element) 40. The thermal photodetector 1 is constituted such that it outputs detection signals (electric signals) corresponding to the intensity of the received light by using the light absorbing layer 50 and the thermal detection element 40.

As shown in FIG. 1, the thermal photodetector 1 has a base member 10 and posts (column members) 20. Furthermore, as shown in FIG. 2, the thermal photodetector 1 also has a support member 30, the thermal detection element 40, and the light absorbing layer 50.

As shown in FIG. 2, the base member 10 includes a substrate 11 and a spacer layer 12 which is formed on the substrate 11. The substrate 11 is formed of a silicon substrate, for example. The substrate 11 is provided with an electric circuit not shown in the drawing. The substrate 11 is constituted such that it is electrically connected to the thermal detection element 40 through the posts 20 (see FIG. 1).

The spacer layer 12 is an insulating layer and formed of SiO₂, for example. On the spacer layer 12, an etching stopper film 13a is formed. The etching stopper film 13a is a film that prevents a layer other than an etching target from being removed in a step of removing a sacrificial layer 14 (see

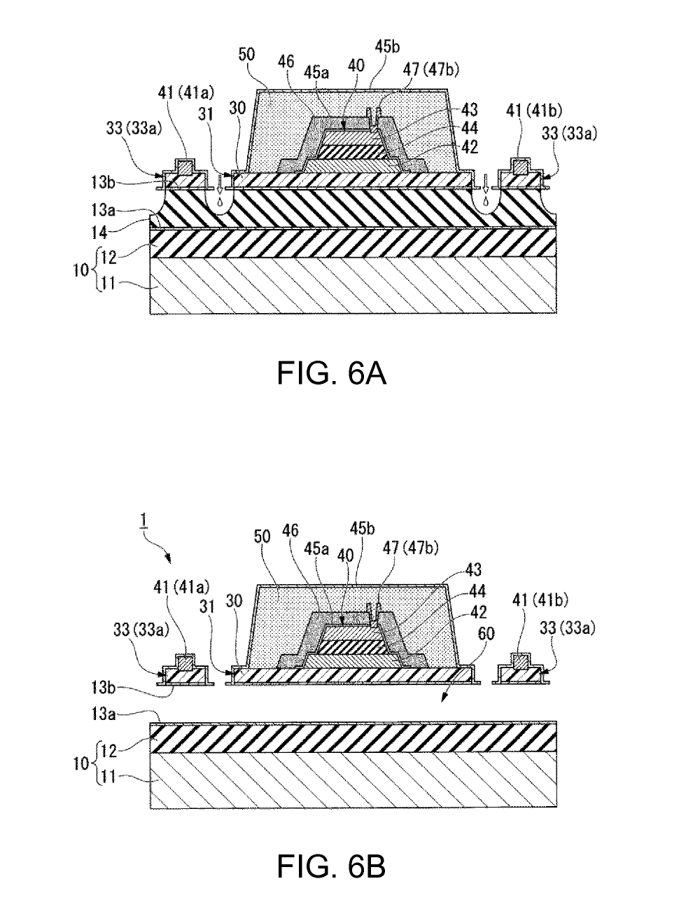

FIGS. 6A and 6B which will be described later) for forming a void portion 60. The etching stopper film 13a is formed of Si₃N₄ or Al₂O₃, for example. An etching stopper film 13b having the same constitution as that of the etching stopper film 13a is formed on the bottom surface of the support member 30.

The posts 20 are erected in the form of columns from the base member 10. As shown in FIG. 1, in the present embodiment, the thermal photodetector 1 has two posts 20, and the posts 20 are constituted so as to support the support member in two points. In each of the posts 20, a plug 21 electrically connected to the thermal detection element 40 is disposed. The plug 21 is connected to an electric circuit (not shown in the drawing) provided in the substrate 11. By pattern-wise etching performed on the sacrificial layer 14 formed of SiO₂ or the like, the posts 20 are selectively formed simultaneously with the void portion 60.

As shown in FIG. 1, the support member (membrane) 30 is supported by the two posts 20. The support member 30 has a main body portion 31 that supports the thermal detection element 40 and the light absorbing layer 50, connection portions 32 that are connected to the posts 20, and arm portions 33 (33a and 33b) that connect the main body portion 31 to the connection portions 32. Two of the arm portions 33 extend from the edge of the main body portion 31 and have a narrow and long shape so as to thermally separate the thermal detection element 40.

On the arm portions 33 (33a and 33b), wiring layers 41 (41a and 41b) are formed. The wiring layer 41a is connected to a first electrode 42 of the thermal detection element 40. The wiring layer 41a extends along the arm portion 33a and is connected to the electric circuit in the substrate 11 through the post 20. The wiring layer 41b is connected to a second electrode 43 of the thermal detection element 40. The wiring layer 41b extends along the arm portion 33b and is connected to the electric circuit in the substrate 11 through the post 20. The wiring layers 41 (41a and 41b) also have a narrow and long shape so as to thermally separate the thermal detection element 40.

The support member 30 can be formed by, for example, patterning a laminate film composed of three layers including a silicon oxide film (SiO)/a silicon nitride film (SiN)/a silicon oxide film (SiO). If the support member 30 has a laminated structure, it is possible to reduce residual stress that causes warpage of the support member 30 by, for example, causing strong residual tensile stress of the nitride film as an intermediate layer to act such that the tensile stress is canceled out by residual compressive stress of the two oxide films as an upper layer and a lower layer. In order to stably support the thermal detection element 40 and the light absorbing layer 50, the support member 30 has a total thickness that satisfies the mechanical strength required. The support member 30 does not need to have a laminated structure, and may be formed of a single SiO₂ layer (first insulating layer).

As shown in FIG. 2, the thermal detection element 40 is supported by the support member 30 such that the void portion 60 is interposed between the thermal detection element 40 and the base member 10. The thermal detection element 40 includes the first electrode (lower electrode) 42, the second electrode (upper electrode) 43, and a pyroelectric material (pyroelectric layer) 44 disposed between the first electrode 42 and the second electrode 43. Both the first electrode 42 and the second electrode 43 can be formed by, for example, laminating three layers of metal films on each other. For example, from the position far from the pyroelectric material 44, iridium (Ir), an oxide of iridium (IrOx), and platina (Pt) can be sputtered so as to form the three layer structure.

The pyroelectric material 44 is constituted with the aforementioned pyroelectric material according to the invention. When heat is transferred to the pyroelectric material 44, due to a pyroelectric effect, a value of electric polarization of the pyroelectric material 44 changes. By detecting a current resulting from the change in the value of electric polarization, the intensity of incident light can be detected.

The pyroelectric material according to the invention has both a high degree of insulating properties and a high remnant polarization value. Therefore, the thermal detection element 40 and the thermal photodetector 1 are highly reliable.

In the thermal detection element (pyroelectric element) 40 of the present embodiment, by the thickness thereof or the material forming the thermal detection element 40, the thermal resistance of the first electrode 42 that comes into contact with the support member 30 is greater than the thermal resistance of the second electrode 43. According to this constitution, heat is easily transferred to the pyroelectric material 44 through the second electrode 43, the heat of the pyroelectric material 44 does not easily escape to the support member 30 through the first electrode 42, and the sensitivity of the thermal detection element 40 is improved.

The thermal detection element 40 is covered with a protective film 45a. In the thermal detection element 40, the outside of the protective film 45a is covered with an insulating layer 46. Generally, when row material gas (TEOS) of the insulating layer 46 causes a chemical reaction, the reducing gas such as hydrogen gas or water vapor is generated. The protective film 45a is a film that protects the thermal detection element 40 from the reducing gas generated in the process of forming the insulating layer 46. The protective film 45a is formed of, for example, Al₂O₃. A portion of the support member 30, the wiring layers 41, and the light absorbing layer 50 are also covered with a protective film 45b having the same constitution as that of the protective film 45a.

The wiring layers 41 (41a and 41b) are wired on the insulating layer 46. Within the insulating layer 46, contact holes 47 (47a and 47b) are formed. As shown in FIG. 2, the contact holes 47 are formed such that they also penetrate the protective film 45. As shown in FIG. 1, the wiring layer 41a conducts electricity together with the first electrode 42 through the contact hole 47a, and the wiring layer 41b conducts electricity together with the second electrode 43 through the contact hole 47b.

The light absorbing layer 50 is formed on the thermal detection element 40 covered with the insulating layer 46. The light absorbing layer 50 radiates heat by absorbing incident light and is formed of, for example, SiO₂. If the second electrode 43 is formed of a metal such as Pt, the top surface of the second electrode 43 can be used as a reflective surface. In this case, if a distance L between the top surface of the light absorbing layer 50 and the top surface of the second electrode 43 is set to be λ/4 (λ represents a wavelength of incident light), an optical resonator (λ/4 optical resonator) by which the light having a wavelength λ undergoes multiple reflection can be constituted. As a result, the light absorbing layer 50 can absorb the light having a wavelength λ with excellent efficiency.

In the thermal photodetector 1 constituted as above, the thermal detection element (pyroelectric element) 40 has the pyroelectric material 44 between the first electrode 42 and the second electrode 43, and is supported by the support member 30 such that the void portion 60 is interposed between the thermal detection element 40 and the base member 10. After entering the light absorbing layer 50, the light undergoes resonance or the like. As a result, the light absorbing layer radiates heat, and the heat is transferred to the pyroelectric material 44. In the pyroelectric material 44, due to a pyroelectric effect, the value of electric polarization changes. The current resulting from the change in the value of electric polarization flows to the electric circuit of the substrate 11 through the wiring layers 41 (41a and 41b). By detecting the current, the intensity of the incident light can be detected.

A thermoelectric conversion element is constituted with the thermal detection element (pyroelectric element) 40, the insulating layer 46, and the light absorbing layer 50.

As described above, the support member 30 in the thermal photodetector 1 has residual stress. When the main body portion 31 undergoes warpage due to the residual stress, as shown in FIG. 1, rotary stress that coils and pulls the arm portions 33 is applied in a plane direction. Due to their properties, the arm portions 33 should be formed as long and thin units. Consequently, in some cases, depending on the magnitude of rotary stress S, the arm portions 33 crack, or the wiring layers 41 of the thermal detection element 40 are broken.

Therefore, as shown in FIG. 1, the thermal photodetector 1 has a first wide portion 70 and a second wide portion 80 in which the arm portions 33 of the support member 30 partially widen.

By the first wide portion 70, the arm portion 33 partially widens in a first connection portion 33A where the arm portion 33 is connected to the main body portion 31. The first wide portion 70 has expansion portions 71a and 71b where the arm portions 33 are partially expanded. The expansion portions 71a and 71b are integrally formed in a state of straddling the main body portion 31 and the arm portion 33. The expansion portions 71a and 71b are formed of the same material as that of the support member 30, and have the same thickness as that of the support member 30. The expansion portions 71a and 71b of the present embodiment are in the form of a rectangle when seen in a plan view. Due to the expansion portions 71a and 71b, the width of the first connection portion 33A is greater than the width of a middle portion of the arm portion 33.

The arm portion 33 has a bending portion 33C that bends along the main body portion 31. That is, the arm portion 33 extend from the main body portion 31, which is in the form of a rectangle when seen in a plan view, in a direction parallel to any one side of the main body portion 31, then bends at a right angle, keeps running in a direction parallel to another side adjacent to aforementioned any one side of the main body portion 31, and is connected to connection portion 32. In this way, the arm portions 33a and 33b, that are L-shaped when seen in a plan view, form point symmetry with respect to the center of the main body portion 31.

By the expansion portion 71a of the first wide portion 70, one side of the arm portions 33 in the width direction that corresponds to an outside 33C1 of a bending portion 33C partially widens in the first connection portion 33A. Furthermore, by the expansion portion 71b of the first wide portion 70, the other side of the arm portions 33 in the width direction that corresponds to an inside 33C2 of bending portions 33C partially widens in the first connection portion 33A. In this way, in the present embodiment, the first wide portion 70 is constituted such that both sides of the arm portion 33 in the width direction that correspond to the inside 33C2 and the outside 33C1 of the bending portion 33C partially widen in the first connection portion 33A.

By the second wide portion 80, the arm portion 33 in the second connection portion 33B where the arm portion 33 is connected to the connection portion 32 partially widens. The second wide portion 80 has expansion portions 81a and 81b where the arm portion 33 is partially expanded. The expansion portions 81a and 81b are integrally formed in a state of straddling the connection portion 32 and the arm portion 33. The expansion portions 81a and 81b are formed of the same material as that of the support member 30, and the thickness of the expansion portions 81a and 81b is the same as that of the support member 30. The expansion portions 81a and 81b according to the invention are in the form of a rectangle when seen in a plan view. Due to the expansion portions 81a and 81b, the width of the first connection portion 33A is greater than the width of a middle portion of the arm portion 33.

By the expansion portion 81a of the second wide portion 80, one side of the arm portion 33 in the width direction that corresponds to an outside 33C1 of a bending portion 33C partially widens in the first connection portion 33A. Furthermore, by the expansion portion 81b of the second wide portion 80, the other side of the arm portion 33 in the width direction that corresponds to inside 33C2 of bending portions 33C partially widens in the first connection portion 33A. In this way, in the present embodiment, the second wide portion 80 is constituted such that both sides of the arm portion 33 in the width direction that correspond to the inside 33C2 and the outside 33C1 of the bending portion 33 partially widen in the first connection portion 33A.

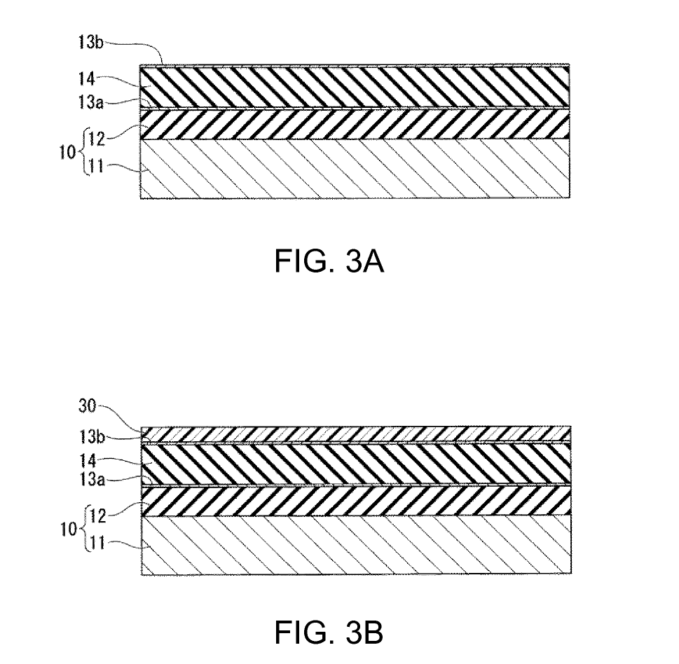

Next, a manufacturing method of the thermal photodetector 1 constituted as above will be described with reference to FIGS. 3A to 6B.

FIGS. 3A to 6B are views in which main steps in a manufacturing method of a thermal photodetector in the first embodiment of the invention are illustrated in chronological order.

First, as shown in FIG. 3A, the spacer layer 12 is formed on the substrate 11. Thereafter, on the spacer layer 12, the etching stopper film (first etching stopper film) 13a is formed, and then the sacrificial layer 14 and the etching stopper film (second etching stopper film) 13b are formed (base member forming step). As a method for forming the etching stopper films 13a and 13b, for example, it is possible to use an atomic layer chemical vapor deposition (ALCVD) method that can adjust the film thickness to the level of atomic size.

Thereafter, as shown in FIG. 3B, a three-layered laminate film which will become the support member 30 is formed on the etching stopper film 13b (membrane forming step).

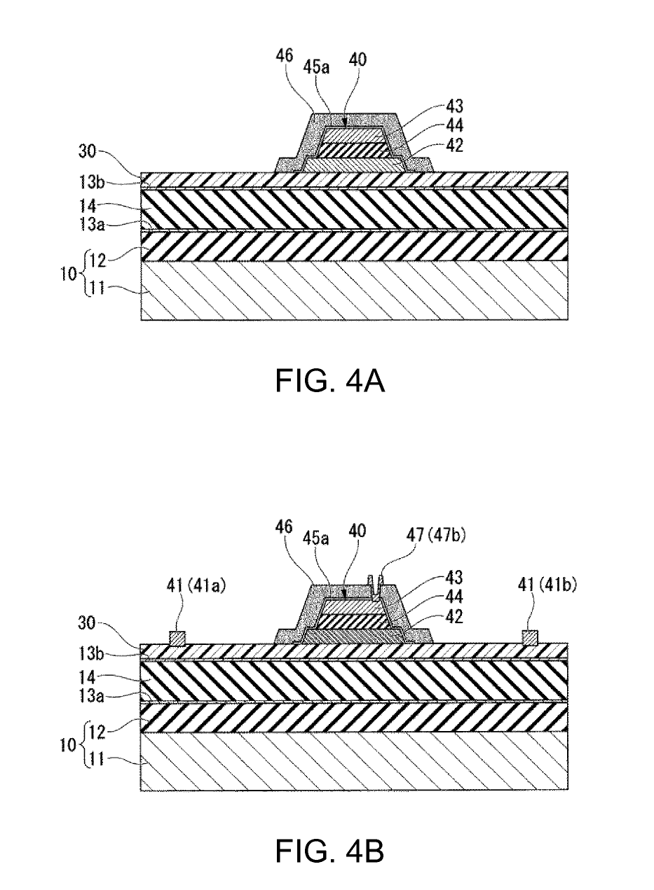

Subsequently, as shown in FIG. 4A, by laminating the first electrode 42, the pyroelectric material 44, and the second electrode 43 on the support member 30, the thermal detection element (pyroelectric element) 40 is formed, and the protective film (first protective film) 45a and the insulating layer 46 are formed (pyroelectric element forming step). As a method for forming the protective film 45a, for example, it is possible to use the atomic layer chemical vapor deposition (ALCVD) method. As a method for forming the insulating layer 46, for example, it is possible to use a general CVD method.

Then, as shown in FIG. 4B, the contact holes 47 (47a and 47b) are formed in each of the first electrode 42 and the second electrode 43 of the thermal detection element 40, and the wiring layers 41 (41a and 41b) are formed (wiring layer forming step). The protective film 45a prevents reducing gas from permeating the thermal detection element 40 at the time of forming the contact holes 47 in the insulating layer 46.

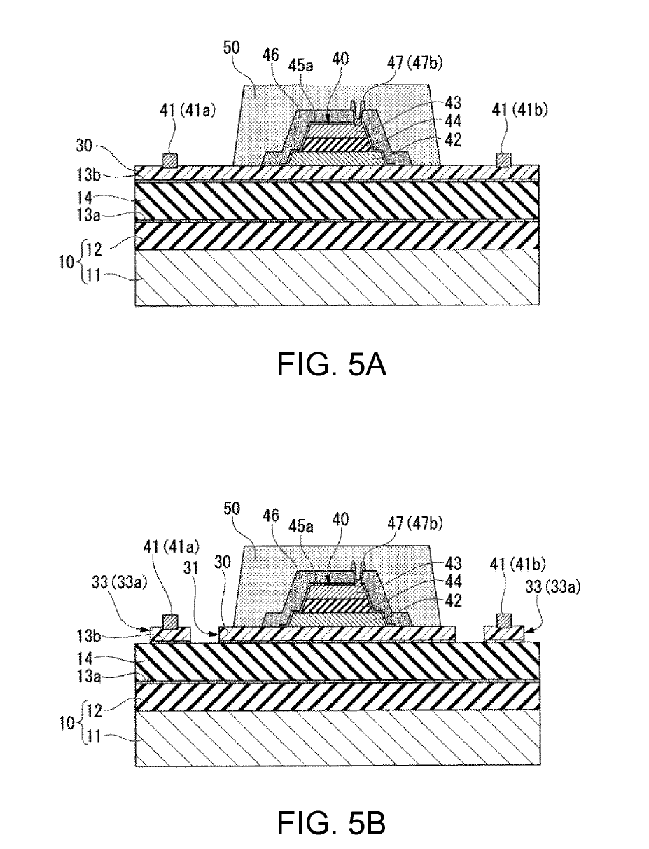

Thereafter, as shown in FIG. 5A, the light absorbing layer 50 is formed and patterned (light absorbing layer forming step). As a method for forming the light absorbing layer 50, for example, it is possible to use a general CVD method. The surface of the light absorbing layer 50 may be smoothened by, for example CMP (chemical mechanical polishing).

Subsequently, as shown in FIG. 5B, the main body portion 31, the connection portions 32, and the arm portions 33 are formed by patterning the support member 30 (membrane processing step). In this step, the expansion portions 71a and 71b of the first wide portion 70 as well as the expansion portions 81a and 81b of the second wide portion 80 are also formed by patterning.

Then, as shown in FIG. 6A, the protective film (second protective film) 45b used at the time of etching the sacrificial layer 14 is formed, and then the sacrificial layer 14 is subjected to wet etching (sacrificial layer etching step). When the wet etching is performed on the sacrificial layer 14, the etching stopper film 13a protects the spacer layer 12, and the etching stopper film 13b protects the support member 30.

Finally, as shown in FIG. 6B, the sacrificial layer 14 is removed by wet etching, thereby forming the void portion (void processing step). By selectively removing the sacrificial layer 14, the posts 20 are formed simultaneously with the void portion 60. By the void portion 60, the support member 30 is separated from the base member 10, and radiation of heat passing through the support member 30 is inhibited. In this way, the thermal photodetector 1 is manufactured.

The thermal photodetector 1 and the pyroelectric element 40 described above include the pyroelectric material according to the invention that has both a high degree of insulating properties and a high remnant polarization value. Therefore, the thermal photodetector 1 and the pyroelectric element 40 are highly reliable.

Particularly, the thermal photodetector 1 constituted as shown in FIG. 1 has the first wide portion 70 by which the arm portion 33 partially widens in the first connection portion 33A where the arm portion 33 is connected to the main body portion 31. According to this constitution, the first connection portion 33A of the arm portion 33 connected to the main body portion 31 in the support member 30 partially widens. Consequently, it is possible to enhance the rigidity of the arm portion 33 in the first connection portion 33A and to inhibit the destruction caused by the residual stress of the support member 30 that is generated in the aforementioned manufacturing steps. Although the heat resistance increases when the arm portion 33 widens, the heat resistance is determined by the minimum width of the arm portion 33. Therefore, if the arm portion 33 partially widens, it is possible to heat from being transferred to the base member 10 through the arm portion 33 and to prevent the deterioration of the detection characteristics of the thermal detection element 40.

The first wide portion 70 is constituted such that both sides of the arm portion 33 in the width direction that correspond to the inside 33C2 and the outside 33C1 of the bending portion 33C partially widen in the first connection portion 33A. In a case in which the arm portion 33 has the bending portion 33C that bends along the main body portion 31 as in the invention, when the rotary stress S that causes the main body portion 31 to coil and pull the arm portion 33 is applied in the plane direction, tensile stress is applied to the outside 33C1 of the bending portion 33C, and compressive stress is applied to the inside 33C2 of the bending portion 33C. Accordingly, if both sides of the arm portion 33 that correspond to the inside 33C2 and the outside 33C1 of the bending portion 33C partially widen in the first connection portion 33A, the rigidity of the arm portions 33 in the first connection portion 33A can be further enhanced.

The thermal photodetector 1 has the second wide portion 80 by which the arm portion 33 in the second connection portion 33B where the arm portion 33 is connected to the connection portion 32 partially widens. According to this constitution, the rigidity of the arm portion 33 in the second connection portion 33B can be enhanced as in the first connection portion 33A, and the destruction caused by the residual stress can be inhibited.

The second wide portion 80 is constituted such that both sides of the arm portion 33 in the width direction that correspond to the inside 33C2 and the outside 33C1 of the bending portion 33C partially widen in the second connection portion 33B. Accordingly, the second wide portion 80 can deal with the tensile stress and the compressive stress resulting from the existence of the bending portion 33C, and the rigidity of the arm portion 33 in the second connection portion 33B can be enhanced.

Therefore, according to the present embodiment described above, the thermal photodetector 1 has the base member 10, the posts 20 that are erected on the base member 10, the support member 30 that is supported by the posts 20, the thermal detection element 40 that is supported by the support member 30 such that the void portion 60 is interposed between the base member 10 and the thermal detection element 40, and the light absorbing layer 50 that is formed on the thermal detection element 40. The support member 30 has the main body portion 31 that supports the thermal detection element 40 and the light absorbing layer 50, the connection portions 32 that are connected to the posts 20, the arm portions 33 that connect the main body portion 31 to the connection portions 32, and the first wide portion 70 by which the arm portions 33 in the first connection portion 33A where the arm portions 33 are connected to the main body portion 31 partially widen. If the aforementioned constitution is adopted, it is possible to effectively inhibit the arm portions 33 from cracking and inhibit the wiring layers 41 of the thermal detection element 40 from being broken. Consequently, the thermal photodetector 1 that can increase the yield is obtained.

According to the aforementioned method, it is possible to manufacture highly reliable thermal photodetector and pyroelectric element (pyroelectric capacitor) with excellent efficiency.

### Second Embodiment

Next, a second embodiment of the thermal photodetector according to the invention will be described.

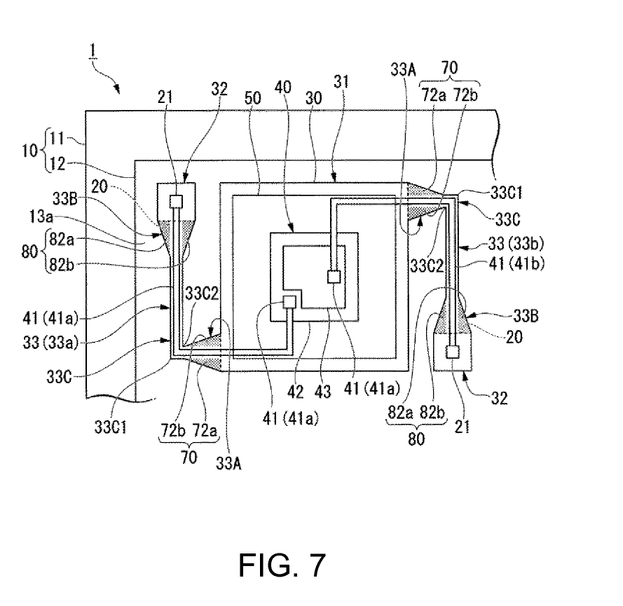

FIG. 7 is a plan view of the thermal photodetector in the second embodiment of the invention. The following description is focused on the differences between the aforementioned embodiment and the second embodiment, and the points common to the first and second embodiments will not be described.

As shown in FIG. 7, the constitution of the first wide portion 70 and the second wide portion 80 of the second embodiment is different from that of the aforementioned embodiment.

The first wide portion 70 of the second embodiment is constituted such that the width of the arm portion 33 gradually increases toward the main body portion 31 in the first connection portion 33A. The first wide portion 70 has expansion portions 72a and 72b in which the arm portion 33 is partially expanded. The expansion portions 72a and 72b are integrally formed in a state of straddling the main body portion 31 and the arm portion 33. The expansion portions 72a and 72b are formed of the same material as that of the support member 30, and the thickness of the expansion portions 72a and 72b is the same as that of the support member 30. Each of the expansion portions 72a and 72b of the present embodiment is in the form of a right-angled triangle when seen in a plan view. Due to the expansion portions 72a and 72b, the width of the first connection portion 33A is greater than the width of the middle portion of the arm portion 33. The first wide portion 70 can be formed by patterning of the aforementioned membrane processing step.

The second wide portion 80 of the second embodiment is constituted such that the width of the arm portion 33 gradually increases toward the connection portion 32 in the second connection portion 33B. The second wide portion 80 has the expansion portions 82a and 82b in which the arm portion 33 is partially expanded. The expansion portions 82a and 82b are integrally formed in a state of straddling the connection portion 32 and the arm portions 33. The expansion portions 82a and 82b are formed of the same material as that of the support member 30, and the thickness of the expansion portions 82a and 82b is the same as that of the support member 30. Each of the expansion portions 82a and 82b of the present embodiment are in the form of a right-angled triangle when seen in a plan view. Due to the expansion portions 82a and 82b, the width of the second connection portion 33B is greater than the width of the middle portion of the arm portion 33. The second wide portion 80 can be formed by patterning of the aforementioned membrane processing step.

According to the second embodiment constituted as above, the width of the arm portion 33 gradually increases toward the main body portion 31 in the first connection portion 33A. Therefore, it is possible to mitigate the stress concentration occurring in the vicinity of the root of the arm portion 33. Consequently, it is possible to enhance the rigidity of the arm portion 33 in the first connection portion 33A, and to inhibit the destruction caused by the residual stress of the support member 30 that is generated in the aforementioned manufacturing steps.

Furthermore, according to the second embodiment constituted as above, the width of the arm portion 33 gradually increases toward the connection portion 32 in the second connection portion 33B. Therefore, it is possible to mitigate the stress concentration occurring in the vicinity of the tip of the arm portion 33. Consequently, as in the first connection portion 33A, it is possible to enhance the rigidity of the arm portions 33 in the second connection portion 33B and to inhibit the destruction caused by the residual stress.

As a result, according to the second embodiment, operation and effect in the aforementioned first embodiment are obtained, and the stress concentration occurring in the vicinity of the root of the arm portions 33 can be mitigated. Therefore, it is possible to effectively inhibit the arm portions 33 from cracking and to inhibit the wiring layers 41 of the thermal detection element 40 from being broken. Consequently, in the second embodiment, the thermal photodetector 1 that can further increase the yield is obtained.

### Third Embodiment

Next, an embodiment of a thermal photodetection apparatus according to the invention will be described.

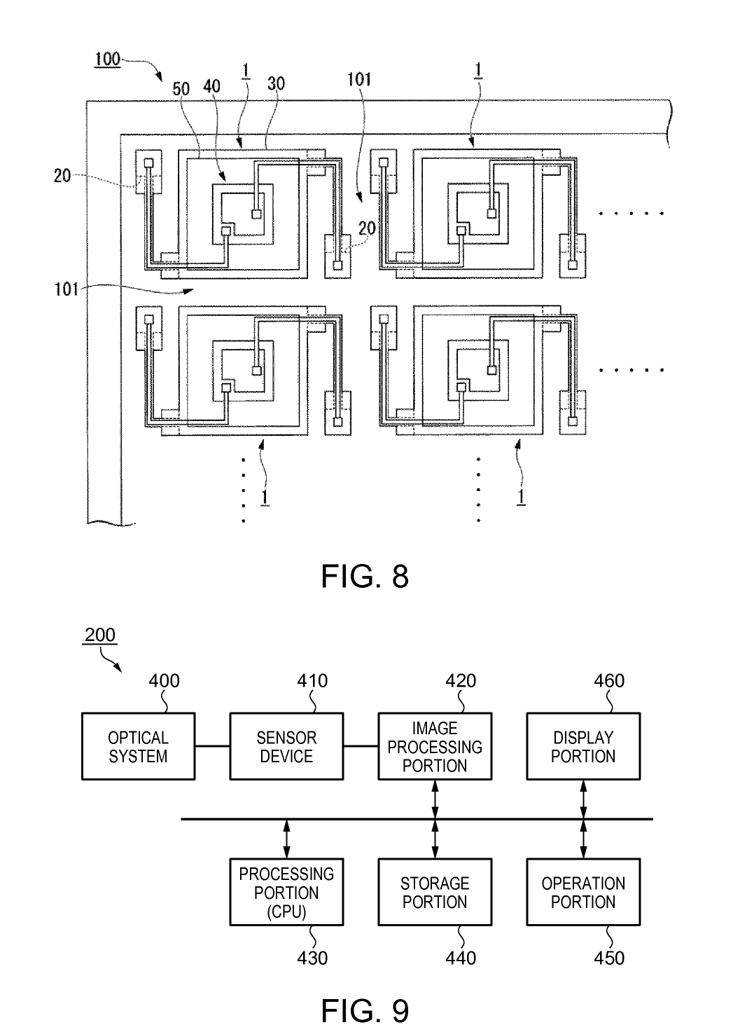

FIG. 8 is a plan view showing a thermal photodetection apparatus in a third embodiment of the invention. The following description is focused on the differences between the aforementioned embodiment and the third embodiment, and the points common to the aforementioned embodiment and the third embodiment will not be repeated.

As shown in FIG. 8, a thermal photodetection apparatus 100 is constituted such that a plurality of thermal photodetectors 1 is two-dimensionally disposed.

In the thermal photodetection apparatus 100, the thermal photodetectors 1 are provided as unit cells and arranged in directions of two axes, for example, in directions of two axes orthogonal to each other. The thermal photodetection apparatus 100 may be constituted with a single thermal photodetector 1 forming one cell. A plurality of posts 20 is erected from the base member 10, and for example, two posts 20 support a single thermal photodetector 1 forming one cell. The thermal photodetectors 1 are arranged in the directions of two axes orthogonal to each other. A single thermal photodetector 1 forming one cell accounts for a region having an area of, for example, 100×100

Each of the thermal photodetectors 1 includes the support member 30 that is connected to two posts 20, the thermal detection element 40, and the light absorbing layer 50. A single thermal photodetector 1 forming one cell accounts for a region having an area of, for example 80×80 μm. A single thermal photodetector 1 forming one cell is connected to two posts 20, and except for this, nothing comes into contact with the single thermal photodetector 1. In the lower portion of the thermal photodetector 1, the void portion 60 (see FIG. 2) is formed. When seen in a plan view, an opening portion 101 that is in communication with the void portion 60 is disposed in the periphery of the thermal photodetector 1. As a result, the single thermal photodetector 1 forming one cell is thermally separated from the base member 10 or a thermal photodetector 1 forming another cell.

According to the third embodiment constituted as above, the thermal photodetection apparatus (thermal optical array sensor) 100 is realized in which the plurality of thermal photodetectors 1 is two dimensionally disposed (for example, the thermal photodetection apparatus 100 is realized in which the plurality of thermal photodetectors 1 is disposed in the form of an array along each of two axes (X-axis and Y-axis) orthogonal to each other).

### Electronic Instrument

Next, an electronic instrument according to the invention will be described.

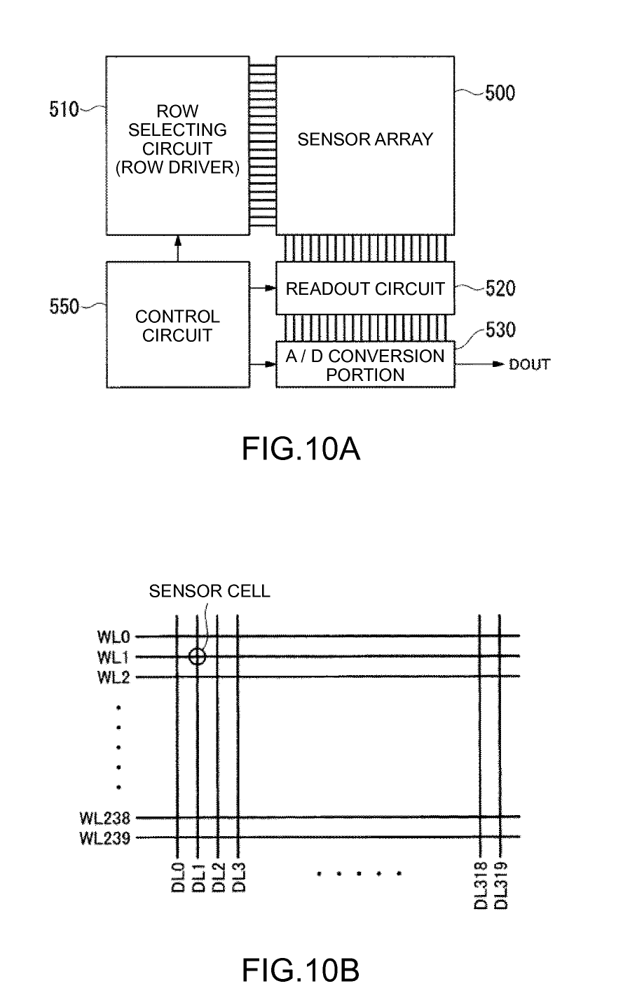

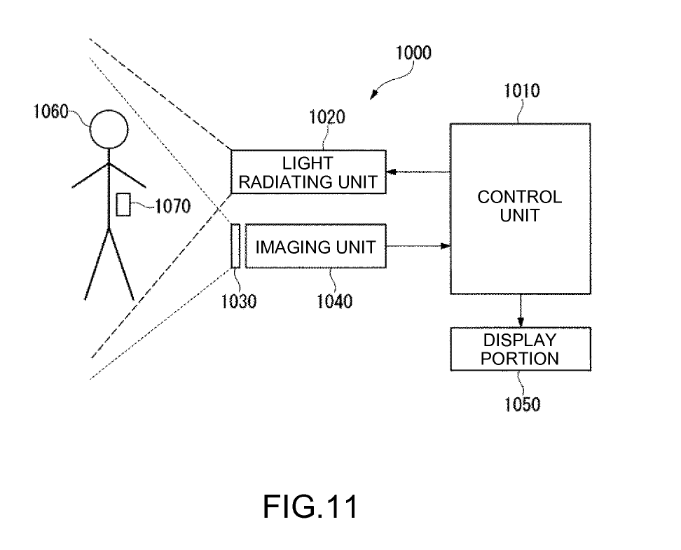

FIG. 9 is a view showing the constitution of an electronic instrument of a preferred embodiment of the invention. FIGS. 10A and 10B are views showing the constitution of a sensor device of the electronic instrument of a preferred embodiment of the invention. FIG. 11 is a view showing the constitution of a terahertz camera as the electronic instrument of a preferred embodiment of the invention.

As shown in FIG. 9, an electronic instrument 200 has a sensor device 410 composed of the thermal photodetector 1 or the thermal photodetection apparatus 100.

The electronic instrument 200 includes an optical system 400, the sensor device 410, an image processing portion 420, a processing portion 430, a storage portion 440, an operation portion 450, and a display portion 460. The electronic instrument 200 of the present embodiment is not limited to the constitution shown in FIG. 9, and can be embodied in various ways in which a portion (for example, the optical system, the operation portion, and the display portion) of the constituents is not used, or other constituents are added.

The optical system 400 includes, for example, a single lens or a plurality of lenses or a driving portion that drives the lenses, and forms an image of an object in the sensor device 410. If necessary, the optical system 400 also performs focus adjustment.

The sensor device 410 is constituted with the two-dimensionally arranged thermal photodetectors 1 and is provided with a plurality of row lines (word lines or scan lines) and a plurality of column lines (data lines). The sensor device 410 can include, in addition to the two-dimensionally arranged detectors, a row selecting circuit (row driver), a readout circuit that reads data out of the detectors through the column lines, an A/D conversion portion, and the like. By sequentially reading data out of each of the two-dimensionally arranged detectors, the sensor device 410 can perform processing of capturing the image of an object.

Based on the digital image data (pixel data) from the sensor device 410, the image processing portion 420 performs various image processing such as image correction processing.

The processing portion 430 controls the entirety of the electronic instrument 200 or controls each block in the electronic instrument 200. The processing portion 430 is realized by, for example, a CPU. The storage portion 440 stores various information, and functions as, for example, a working region of the processing portion 430 or the image processing portion 420. The operation portion 450 functions as an interface that a user uses for operating the electronic instrument 200. The operation portion 450 is realized by, for example, various buttons or a graphical user interface (GUI) screen. The display portion 460 displays, for example, an image obtained by the sensor device 410 or the GUI screen. The display portion 460 is realized by various displays such as a liquid crystal display or an organic EL display.

In this way, by using a single thermal photodetector forming one cell as a sensor and by two-dimensionally disposing the thermal photodetectors 1, each of which forms one cell, in directions of two axes, for example, in directions of two axes orthogonal to each other, the sensor device 410 can be constituted. If the sensor device 410 is constituted in this way, it is possible to provide a heat distribution image resulting from electromagnetic waves. The electronic instrument 200, which uses a terahertz camera for detecting a specific substance, determining counterfeit money, detecting chemicals in envelopes, and a non-destructive inspection of buildings, and the like, can be constituted with the sensor device 410.

FIG. 10A shows an example of the constitution of the sensor device 410 of FIG. 9. The sensor device includes a sensor array 500, a row selecting circuit (row driver) 510, and a readout circuit 520. The sensor device can also include an A/D conversion portion 530 and a control circuit 550. A high-performance terahertz camera can be realized by using the sensor device.

In the sensor array 500, for example, a plurality of sensor cells is arranged (disposed) in directions of two axes as shown in FIG. 8. Furthermore, a plurality of row lines (word lines or scan lines) and a plurality of column lines (data lines) are provided in the sensor array 500. Herein, the sensor array 500 has one column line or one row line. For example, when the sensor array 500 has one row line, a plurality of sensor cells is arranged in a direction (horizontal direction) along the row line in FIG. 10A. In contrast, when the sensor array 500 has one column line, a plurality of sensor cells is arranged in a direction (vertical direction) along the column line.

As shown in FIG. 10B, each of the sensor cells of the sensor array 500 is disposed (formed) in a place corresponding to the position in which each row line and each column line cross each other. For example, the sensor cell shown in FIG. 10B is disposed in a place corresponding to the position in which a row line WL1 and a column line DL1 cross each other. Other sensor cells are also disposed in the same manner.

The row selecting circuit 510 is connected to one row line or a plurality of row lines, and performs an operation of selecting the respective row lines. For example, for the QVGA (320×240 pixels) sensor array (focal plane array) 500 shown in FIG. 10B, the row selecting circuit 510 performs an operation of sequentially selecting (scanning) the row lines in order of WL0, WL1, WL2, . . . , and WL239. That is, the row selecting circuit 510 outputs the signals (word selection signals) for selecting these row lines to the sensor array 500.

The readout circuit 520 is connected to one column line or a plurality of column lines, and performs an operation of reading the respective column lines. For example, in the QVGA sensor array 500, the readout circuit 520 performs an operation of reading detection signals (detection current or detection charge) out of column lines DLO, DL1, DL2, DL3, . . . , and DL319.

The A/D conversion portion 530 performs processing for conducting A/D conversion by which the detection voltage (measurement voltage or ultimate voltage) obtained in the readout circuit 520 is converted into digital data, and outputs digital data DOUT obtained after the A/D conversion. Specifically, the A/D conversion portion 530 is provided with A/D converters each of which corresponds to each of the plurality of column lines. Each of the A/D converters performs A/D conversion processing on the detection voltage obtained by the readout circuit 520 in the corresponding column line. The A/D conversion portion 530 may be provided with one A/D converter corresponding to a plurality of column lines, and may perform A/D conversion on the detection voltage of the plurality of column lines in a time-sharing manner by using the single A/D converter.

The control circuit (timing generating circuit) 550 generates various control signals and outputs the control signals to the row selecting circuit 510, the readout circuit 520, and the A/D conversion portion 530. For example, the control circuit 550 generates and outputs control signals for charge or discharge (reset). Alternatively, the control circuit 550 generates and outputs signals for controlling the timing of each circuit.

FIG. 11 shows a terahertz camera 1000 including the sensor device 410 of the present embodiment. The electromagnetic wave absorbing material of the light absorbing layer 50 of the sensor device 410 is set such that the absorption wavelength thereof is optimized for terahertz waves. FIG. 11 shows an example in which the terahertz camera 1000 is combined with a terahertz light radiating unit.

The terahertz camera 1000 is constituted with a control unit 1010, a light radiating unit 1020, an optical filter 1030, an imaging unit 1040, and a display portion 1050. The imaging unit 1040 is constituted with an optical system such as lens not shown in the drawing and a sensor device in which the absorption wavelength of the electromagnetic wave absorbing material of the light absorbing layer 50 of the thermal photodetector 1 is optimized in a terahertz band.

The control unit 1010 includes a system controller that controls the entirety of the terahertz camera 1000, and the system controller controls a light source driving portion and an image processing unit included in the control unit. The light radiating unit 1020 includes a laser apparatus, which emits terahertz light (referring to electromagnetic waves having a wavelength in a range of equal to or greater than 100 μm and equal to or less than 1,000 μm), and an optical system, and radiates the terahertz light to a human being 1060 who is a test object. The terahertz light reflected from the human being 1060, through the optical filter 1030, which passes only an optical spectrum of a specific substance 1070 that is a detection target, is received by the imaging unit 1040. The image signals generated in the imaging unit 1040 are subjected to a predetermined imaging processing in the image processing unit of the control unit 1010 and then output to the display portion 1050. Depending on whether or not the specific substance 1070 is present in the clothes of the human being 1060, the intensity of the signals of the received light changes, and therefore the presence of the specific substance 1070 can be determined.

The aforementioned electronic instrument according to the invention has the thermal photodetector including the pyroelectric material according to the invention that has both a high degree of insulating properties and a high remnant polarization value. Accordingly, the electronic instrument is highly reliable.

Hitherto, preferred embodiments of the invention have been described, but the invention is not limited thereto.

For example, in the thermal photodetector and the electronic instrument according to the invention, the constituents of each portion may be replaced with any constituent that performs the same function, or any constituent may be added to the constituents of each portion.

The invention can be suitably applied to various thermal photodetectors. Examples of the electronic instrument according to the invention include an infrared sensor apparatus, a thermography camera, a night camera for vehicles, a monitoring camera, and the like, but the electronic instrument is not limited to these.

### EXAMPLES

Hereinafter, the invention will be more specifically described based on examples, but the invention is not limited to the examples. In the following description, in a case in which temperature conditions are not specified for processing, the processing is performed at room temperature (25° C.) Furthermore, in a case in which particularly temperature conditions are not specified regarding various measurement conditions, the measurement conditions are numerical values set at room temperature (25° C.)

### 1. Manufacturing Pyroelectric Material

### Example 1

Bismuth acetate, lanthanum acetate, iron acetate, manganese acetate, and titanium tetraisoproxide were prepared at a predetermined ratio, mixed together by being put into a propionic acid solution, and then heated under a condition of 140° C.×120 minutes.

The mixture solution obtained in this way was applied onto a Pt film (first electrode) having a thickness of 200 nm and then subjected to heating processing, thereby forming a pyroelectric material (pyroelectric layer) having a thickness of 400 nm. The formed pyroelectric material was constituted with an oxide containing iron, manganese, bismuth, lanthanum and titanium. In the pyroelectric material, a ratio of the number of the manganese atoms to the sum of the number of the iron atoms, the number of the manganese atoms, and the number of the titanium atoms was 1.0 at %, a ratio of the number of the titanium atoms to the sum of the number of the iron atoms, the number of the manganese atoms, and the number of the titanium atoms was 3.0 at %, and a ratio of the number of the lanthanum atoms to the sum of the number of the bismuth atoms and the number of the lanthanum atoms was 20.0 at %.

Thereafter, in a state in which a portion of the laminate of the first electrode and the pyroelectric material was masked with a polyimide tape, sputtering was performed. In this way, a Pt film (second electrode) having a thickness of 200 nm was formed on a portion of the surface of the pyroelectric material (the surface of the pyroelectric material that was opposite to the surface facing the first electrode).

### Examples 2 to 7

A laminate of a first electrode, a pyroelectric material, and a second electrode was manufactured in the same manner as in Example 1, except that the mixing ratio between solutions of the respective fatty acid metal salts used for preparing the mixture solution was changed such that the composition of the formed pyroelectric material became the composition shown in Table 1.

### Examples 1 to 3

A laminate of a first electrode, a pyroelectric material, and a second electrode was manufactured in the same manner as in Example 1, except that the mixing ratio between solutions of the respective fatty acid metal salts used for preparing the mixture solution was changed such that the composition of the formed pyroelectric material became the composition shown in Table 1.

The composition of the pyroelectric material of each of the examples and comparative examples is summarized in Table 1. In Table 1, the column of “Mn ratio” shows a ratio of the number of the manganese atoms to the sum of the number of the iron atoms, the number of the manganese atoms, and the number of the titanium atoms; the column of “Ti ratio” shows a ratio of the number of the titanium atoms to the sum of the number of the iron atoms, the number of the manganese atoms, and the number of the titanium atoms; the column of “Fe ratio” shows a ratio of the number of the iron atoms to the sum of the number of the iron atoms, the number of the manganese atoms, and the number of the titanium atoms; the column of “Bi ratio” shows a ratio of the number of the bismuth atoms to the sum of the number of the bismuth atoms and the number of the lanthanum atoms; and the column of “La ratio” shows a ratio of the number of the lanthanum atoms to the sum of the number of the bismuth atoms and the number of the lanthanum atoms.

TABLE 1

| | composition of pyroelectric material | | | | |
|---|---|---|---|---|---|
| | Mn ratio | Ti ratio | Fe ratio | La ratio | Bi ratio |
| | [at %] | [at %] | [at %] | [at %] | [at %] |
| Example 1 | 1.0 | 3.0 | 96.0 | 20.0 | 80.0 |
| Example 2 | 1.6 | 1.5 | 96.9 | 14.0 | 86.0 |
| Example 3 | 1.0 | 4.0 | 95.0 | 18.0 | 82.0 |
| Example 4 | 2.0 | 3.0 | 95.0 | 16.0 | 84.0 |
| Example 5 | 1.0 | 0 | 99.0 | 20.5 | 79.5 |
| Example 6 | 1.8 | 0.7 | 97.5 | 9.0 | 81.0 |
| Example 7 | 1.3 | 2.5 | 96.2 | 21.0 | 77.0 |
| Comparative | 0.9 | 3.0 | 96.1 | 20.0 | 80.0 |
| example 1 | | | | | |
| Comparative | 2.1 | 3.0 | 94.9 | 20.0 | 80.0 |
| example 2 | | | | | |
| Comparative | 1.0 | 4.1 | 94.9 | 20.0 | 80.0 |
| example 3 | | | | | |

### 2. Evaluation

2.1 Measurement of Remnant Polarization Value (Electric Polarization Value)

In each of the examples and comparative examples, by using an FCE ferroelectric material evaluation system (manufactured by TOYO Corporation), one-sided triangular waves as a pre-waveform at a peak voltage of −20 V measured at temperature 25° C. were applied to the pyroelectric material, and after 2 seconds, standard triangular waves at a peak voltage of 20 V (+20 V→−20V) was applied to the pyroelectric material. At this time, a remnant polarization value was measured and evaluated according to the following criteria. Herein, a driving frequency was 1 kHz.
A: The remnant polarization value was equal to or greater than 100 μC/cm².
B: The remnant polarization value was equal to or greater than 97 μC/cm² and less than 100 μC/cm².
C: The remnant polarization value was equal to or greater than 94 μC/cm² and less than 97 μC/cm².
D: The remnant polarization value was equal to or greater than 91 μC/cm² and less than 94 μC/cm².
E: The remnant polarization value was less than 91 μC/cm².

### 2.2 Measurement of Leakage Current (Evaluation of Insulating Properties)

For each of the examples and comparative examples, a voltage was applied between the first electrode and the second electrode of the laminate of the first electrode, the pyroelectric material, and the second electrode manufactured as above. At this time, the amount of leakage current was measured and evaluated according to the following criteria.

### Leakage Current at the Time of Applying 60 μV

A: The leakage current was less than 1.0 E−10 A·cm².

B: The leakage current was equal to or greater than 1.0 E−10 A·cm⁻² and less than 3.3 E−10 A·cm⁻².

C: The leakage current was equal to or greater than 3.3 E−10 A·cm ² and less than 6.7 E−10 A·cm ².

D: The leakage current was equal to or greater than 6.7 E−10 A·cm ² and less than 1.0 E−9 A·cm ².

E: The leakage current was equal to or greater than 1.0

E−9 A·cm⁻².

### Leakage Current at the Time of Applying 12 V

A: The leakage current was less than 1.2 E−4 A·cm ².

B: The leakage current was equal to or greater than 1.2 E−4 A·cm ² and less than 1.2 E−3 A·cm ².

C: The leakage current was equal to or greater than 1.2 E−3 A·cm ² and less than 1.2 E−2 A·cm².

D: The leakage current was equal to or greater than 1.2 E−2 A·cm² and less than 1.2 E−1 A·cm².

E: The leakage current was equal to or greater than 1.2 E−1 A·cm²

The results are summarized in Table 2.

TABLE 2

| | | Evaluation of insulating properties | |
|---|---|---|---|
| | Remnant | Leakage current | Leakage current |
| | polarization | at the time of | at the time of |
| | value | applying 60 μV | applying 12 V |
| Example 1 | A | A | A |
| Example 2 | A | A | A |
| Example 3 | A | A | A |
| Example 4 | A | B | A |
| Example 5 | A | C | A |
| Example 6 | C | C | A |
| Example 7 | C | A | A |
| Comparative | A | A | E |
| example 1 | | | |
| Comparative | A | E | A |
| example 2 | | | |
| Comparative | C | A | A |
| example 3 | | | |

As is evident from Table 2, in the invention, a pyroelectric material which had both a high degree of insulating properties and a high remnant polarization value was obtained. In contrast, in comparative examples, satisfactory results were not obtained.

The entire disclosure of Japanese Patent Application No. 2014-205778 filed Oct. 6, 2014 is expressly incorporated by reference herein.

What is claimed is:

1. A pyroelectric material comprising an oxide containing iron, manganese, bismuth, and lanthanum,
wherein a ratio of the number of the manganese atoms to the sum of the number of the iron atoms, the number of the manganese atoms, and the number of titanium atoms is equal to or greater than 1.0 at % and equal to or less than 2.0 at %, and
a ratio of the number of the titanium atoms to the sum of the number of the iron atoms, the number of the manganese atoms, and the number of the titanium atoms is equal to or greater than 0 at % and equal to or less than 4.0 at %.

2. The pyroelectric material according to claim 1,
wherein a ratio of the number of the lanthanum atoms to the sum of the number of the bismuth atoms and the number of the lanthanum atoms is equal to or greater than 10 at % and equal to or less than 20 at %.

3. A manufacturing method of a pyroelectric material, comprising heating a solution obtained by dissolving fatty acid metal salts in an organic solvent so as to manufacture a pyroelectric material constituted with an oxide containing iron, manganese, bismuth, and lanthanum,
wherein in the pyroelectric material, a ratio of the number of the manganese atoms to the sum of the number of the iron atoms, the number of the manganese atoms, and the number of titanium atoms is equal to or greater than 1.0 at % and equal to or less than 2.0 at %, and a ratio of the number of the titanium atoms to the sum of the number of the iron atoms, the number of the manganese atoms, and the number of the titanium atoms is equal to or greater than 0 at % and equal to or less than 4.0 at %.

4. A pyroelectric element comprising:
a first electrode;
the pyroelectric material according to claim 1; and
a second electrode.

5. A pyroelectric element comprising:
a first electrode;
the pyroelectric material according to claim 2; and
a second electrode.

6. A pyroelectric element comprising the pyroelectric material manufactured by the manufacturing method according to claim 3.

7. A manufacturing method of a pyroelectric element, comprising laminating a first electrode, the pyroelectric material according to claim 1, and a second electrode on each other.

8. A manufacturing method of a pyroelectric element, comprising laminating a first electrode, the pyroelectric material according to claim 2, and a second electrode on each other.

9. A thermoelectric conversion element comprising:
the pyroelectric element according to claim 4;
a light absorbing layer; and
an insulating layer disposed between the pyroelectric element and the light absorbing layer.

10. A manufacturing method of a thermoelectric conversion element, comprising:
forming the pyroelectric element according to claim 4; and
forming a light absorbing layer via an insulating layer such that the light absorbing layer covers at least a portion of the pyroelectric element.

11. A thermal photodetector comprising the pyroelectric element according to claim 4.

12. A thermal photodetector comprising the pyroelectric element according to claim 5.

13. A thermal photodetector comprising the pyroelectric element according to claim 6.

14. A thermal photodetector comprising the pyroelectric element manufactured by the manufacturing method according to claim 7.

15. A manufacturing method of a thermal photodetector, comprising:
preparing a base member having a substrate and a sacrificial layer;
forming a support member on a surface of the base member that is a surface on which the sacrificial layer is disposed;
forming the pyroelectric element according to claim 4 on the support member;
forming a light absorbing layer via an insulating layer such that the light absorbing layer covers the outer surface of the pyroelectric element;
patterning the support member; and
etching the sacrificial layer.

16. An electronic instrument comprising the thermal photodetector according to claim 11.

17. An electronic instrument comprising the thermal photodetector according to claim 12.

18. An electronic instrument comprising the thermal photodetector according to claim 13.

19. An electronic instrument comprising the thermal photodetector according to claim 14.

20. An electronic instrument comprising the thermal photodetector manufactured by the manufacturing method according to claim 15.
